(19) United States
(12) Patent Application Publication
(10) Pub. No.: US 2004/0239418 A1
(43) Pub. Date: Dec. 2, 2004

(54) Mute circuit and BTL audio amplifier apparatus

(76) Inventor: Ryosuke Inagaki, Kyoto (JP)

Correspondence Address: MATTINGLY, STANGER & MALUR, P.C., Suite 370, 1800 Diagonal Road, Alexandria, VA, 22314, US

(21) Appl. No.: 10/849,056

(22) Filed: May 20, 2004

(30) Foreign Application Priority Data
May 28, 2003 (JP) 2003-150243

(51) Int. Cl. H04B 15/00; H03F 1/14

(52) U.S. Cl. 330/51; 381/94.5

(57) ABSTRACT

In the present invention, a BTL circuit formed in an IC is constituted in such a manner that a second output stage amplifier receives an output of a first output stage amplifier and generates an inverted output and a switch circuit is provided between any one of the outputs of the first and second output stage amplifier and a speaker, wherein through effecting a muting by making use of a delay time of BTL operation of the second output stage amplifier or alternatively, by making use of switches of respective push-pull structured transistors in place of the switch circuit, an early muting from the time of power source turning ON can be realized.

### BACKGROUND OF THE INVENTION

1. Field of The Invention

The present invention relates to a mute circuit and a BTL audio amplifier apparatus and more specifically, relates to a mute circuit suitable for a BTL circuit formed in an IC, which prevents a pop noise generated such as at a time of a power source throw-in, is formed in a small circuit scale and permits shortening of the mute time thereof, and relates to a BTL audio amplifier apparatus using the same.

2. Conventional Art

In an audio amplifier apparatus using such as transistors, at the time of turning ON a power amplifier, an unpleasant abnormal sound such as a so called pop noise is generated from a speaker, and in the worst case, the speaker may be damaged via the power amplifier. Therefore, a mute circuit is generally provided in an audio amplifier apparatus and a path for audio signals is forcedly interrupted or grounded until such as a power amplifier reaches a steady and stable state, which is known and disclosed in JP (U)-A-1-67818 (document 1), and in which a relay switch circuit is provided between an output terminal of an ordinary power amplifier, not a BTL circuit, and a speaker, and through turning OFF the relay switch circuit, a muting is effected.

Further, as one of muting measures, JP-B-6-11090 (document 2) is known and discloses a mute circuit, in which such as a capacitor is inserted in a drive stage, in response to a power switch throw-in the capacitor is charged and after a predetermined time an audio signal is output to an output stage.

On one hand, as a circuit in a BTL circuit for preventing a pop noise such as at a time of a power source throw-in, JP-A-11-112239 (document 3) is known and discloses a mute circuit in which an operation point adjusting circuit is provided between a differential amplifier circuit in a drive stage and a bias circuit thereof, and the differential amplifier circuit and the bias circuit are turned ON/OFF differently.

When applying the conventional mute circuit as disclosed in document 1 or 2 to a BTL circuit formed as an audio IC, there arise problems of enlarging the circuit scale thereof and of prolonging a time from the start to release of the muting up to several hundreds m sec. In particular, different from a conventional audio field, in a field of small size electronic apparatus such as a cellular phone, a portable type terminal apparatus, a fixed phone and a personal computer, a shortening of a mute time is required, namely, a mute time of a few tens m sec. or less than that is demanded. For this reason, the conventional mute circuit as disclosed in document 1 or 2 is not suitable for an application to an audio IC in the field of the small size electronic apparatus.

On one hand, in the BTL circuit as disclosed in document 3, the mute circuit is required to control the differential amplifier circuit and the bias circuit in the drive stage. However, in the field such as a cellular phone, a portable type terminal apparatus, a fixed phone and a note type personal computer, since the circuit scale of the audio IC is restricted, there is a problem that the mute circuit is difficult to be assembled therein.

In addition, the pop noise is usually generated in a time range of about 10 m sec.˜20 m sec. from the time point of turning ON/OFF of a power source switch, however, in the field of the small size electronic apparatus, since the audio output power is small, in that less than a few watts and the power source voltage is lower than that of a usual acoustic apparatus in an audio field, there arises a problem of prolonging the mute time with a muting operation by means of a time constant circuit such as a capacitor.

### SUMMARY OF THE INVENTION

An object of the present invention is to provide a mute circuit suitable for a BTL circuit formed in an IC, which prevents a pop noise generated such as at a time of a power source throw-in, is formed in a small circuit scale and permits shortening of the mute time.

Another object of the present invention is to provide a BTL audio amplifier apparatus with a mute circuit suitable for a BTL circuit formed in an IC, which prevents a pop noise generated such as at a time of a power source throw-in, is formed in a small circuit scale and permits shortening of the mute time.

A mute circuit or a BTL audio amplifier apparatus according to a first aspect of the invention is constituted in such a manner that in the mute circuit in a BTL circuit formed in an IC which drives a speaker by a first output stage amplifier and a second output stage amplifier which generates an inverted output signal with respect to an output signal of the first output stage amplifier, the second output stage amplifier receives the output signal of the first output stage amplifier as an input and generates the inverted output signal, a switch circuit is provided between any one of the outputs of the first and second output stage amplifier and a terminal of the speaker and through a mute signal the switch circuit is turned OFF for a predetermined interval to effect muting.

Further, a second aspect of the invention is constituted in such a manner that each of the output stages of the first and second output stage amplifier is an operational amplifier constituted by push-pull structured transistors and instead of providing the switch circuit, by making use of the respective push-pull structured transistors as switches and turning OFF these transistors for a predetermined interval, any one of the outputs of the first and second output stage amplifier is set at a high impedance to effect muting.

An operation of the BTL circuit is started by operations of the first and second output stage amplifier. Since the present invention is constituted in such a manner that the second output stage amplifier receives an output signal of the first output stage amplifier and generates an inverted output signal, there exists a time lag after generation of the output signal from the first output stage amplifier and reception of the output signal by the second output stage amplifier as an input signal to the generation of the output signal thereby.

Because of the existence of the time lag, a path for an output signal to the speaker is interrupted through generation of a mute signal at an early time from the power source starting time point, which permits to effect muting at an early time.

Accordingly, in the first aspect of the invention, through the provision of the switch circuit between any one of the outputs of the first and second output stage amplifier and a terminal of the speaker and by turning OFF the switch circuit, a muting is directly effected to the output signal. For this reason the mute time can be shortened. Further, since the muting can be effected only by turning OFF the switch circuit, a time constant circuit such as a capacitor is not required in a drive circuit, thereby, the mute circuit is simplified. As a result, a circuit suitable for a BTL circuit formed in an IC is obtained.

Still further, in the second aspect of the invention, in place of the switch circuit, since the respective push-pull structured transistors are used as switches, an early muting can be effected likely.

As a result, the circuit scale of the mute circuit in the BTL audio amplifier apparatus is reduced as well as the mute time is shortened. Thereby, a mute circuit of a simple structure and suitable for a BTL circuit formed in an IC and a BTL audio amplifier apparatus are realized.

### BRIEF DESCRIPTION OF THE DRAWINGS

FIG. 1 is a block diagram of one embodiment of a BTL audio amplifier apparatus to which a mute circuit of the present invention is applied; and

FIG. 2 is a block diagram of another embodiment of a BTL audio amplifier apparatus to which a mute circuit of the present invention is applied.

### DETAILED DESCRIPTION OF THE EMBODIMENTS

A BTL audio amplifier apparatus 10 is an audio amplifier circuit having a small output watts which is incorporated in a small size electronic apparatus such as a cellular phone, a portable type terminal apparatus, a fixed phone and a note type personal computer, and is formed in an IC. A portion indicated by solid lines in the drawing is the IC. The BTL audio amplifier apparatus 10 is constituted by a preamplifier 1, output stage amplifiers (OP) 2,3 each of which is constituted by an operational amplifier of a push-pull operation, output terminals 4,5, an analog switch 6 connected between the output stage amplifier 3 and the output terminal 5, a resistor R, an one shot circuit 7, an inverter 8, a power source switch SW and a power source terminal 9 which receives an electric power via the power source switch SW. Further, +VDD is a power source line.

Since an audio output power of the BTL audio amplifier apparatus 10 is small such as less than a few watts, different from a BTL circuit such as in an amplifier apparatus for a car audio, an output signal of the output stage amplifier 2 is input to the output stage amplifier 3 of an inverting operation via the resistor R. Thereby, a size reduction of the entire amplifier circuit is designed as well as a time lag is provided with respect to the generation of an output signal of the output stage amplifier 3.

Further, the resistance value of the resistor R is about a few tens k Ω. Still further, since the output electric power of the output stage amplifiers 2,3 is small, for example, such as an operational amplifier circuit of CMOS can be used. An illustration of such as a microphone input terminal, a voice synthesis and generation circuit and a sound volume adjustment circuit is omitted from the drawing.

The output stage amplifier 2 receives an audio signal amplified by the preamplifier 1 and after amplifying the same outputs at the output terminal 4 as well as inputs the output signal to the output stage amplifier 3 of an inverting operation via the resistor R. Since the output stage amplifier 3 is an inverting amplifier, the output stage amplifier 3 inverts the input signal and outputs an amplified audio signal at the output terminal 5 via the analog switch 6.

A speaker 11 is connected between the output terminals 4 and 5.

The one shot circuit 7 is a mute signal generation circuit, is triggered, when the power source switch SW is turned ON, by the rising signal thereof and generates a pulse P having a pulse width in a range of about 30 m sec.˜50 m sec. The analog switch 6 is a transmission gate constituted by P channel and N channel MOS transistors and is turned OFF during a period when the pulse P is “H” (High level). Thereby, a generation of a pop noise at the time of power source throw-in is prevented.

Further, to the IC for the BTL audio amplifier apparatus 10 an electric power is fed via the power source switch SW and the power source terminal 9 and the electric power is also fed to the one shot circuit 7. Still further, the output of the one shot circuit 7 is input to a inverting input terminal of the analog switch 6 and an input terminal of the inverter 8 and is inverted by the inverter 8 and is then input to a non-inverting input terminal of the analog switch 6.

When the power source switch SW is turned OFF, the one shot circuit 7 is operated by the falling signal at the time of the power source turning OFF and likely, the analog switch 6 is turned OFF for a predetermined interval. Further, in order that the one shot circuit 7 can be triggered even by a falling signal, it is sufficient, for example, if such as an inverter is provided inside the circuit line of the rising signal in an OR connection and the falling signal is used for the triggering after converting the same to a rising signal.

In the embodiment, since the electric power for the one shot circuit 7 is fed at the downstream of the power source switch SW, the initial state of the analog switch 6 is kept in OFF (at a high impedance). The one shot circuit 7 generates “H” at the same time when the power source is turned ON. On one hand, at the time of when the power source is turned OFF, since the output of the one shot circuit 7 is not generated because of the power source turning OFF, the one shot circuit 7 is constituted to incorporate such as a capacitor inside thereof to ensure an electric power for the operation so as to delay the turning OFF for a predetermined time and to maintain the operation of the one shot circuit 7.

When an electric power is fed to the one shot circuit 7 from the upstream of the power source switch SW via such as an OFF delaying switch circuit, the above referred to circuit structure is unnecessitated.

As will apparent from the above, through the provision of the analog switch 6 between the output of the output stage amplifier 3 and the speaker 11 and by the direct interruption of the output signal to the speaker 11, the (one) side of the output terminal 5 is floated and the current flow to the speaker 11 is immediately interrupted. Thereby, a generation of pop noise at the speaker 11 can be directly prevented in a high response time.

As a result, the mute time at the time of power source turning ON or OFF can be shortened. Further, in this instance the generation of a mute signal by means of a time constant circuit such as a capacitor is unnecessitated, and the structure of the mute circuit is simplified. As the result, a circuit suitable for a BTL circuit formed in an IC is obtained.

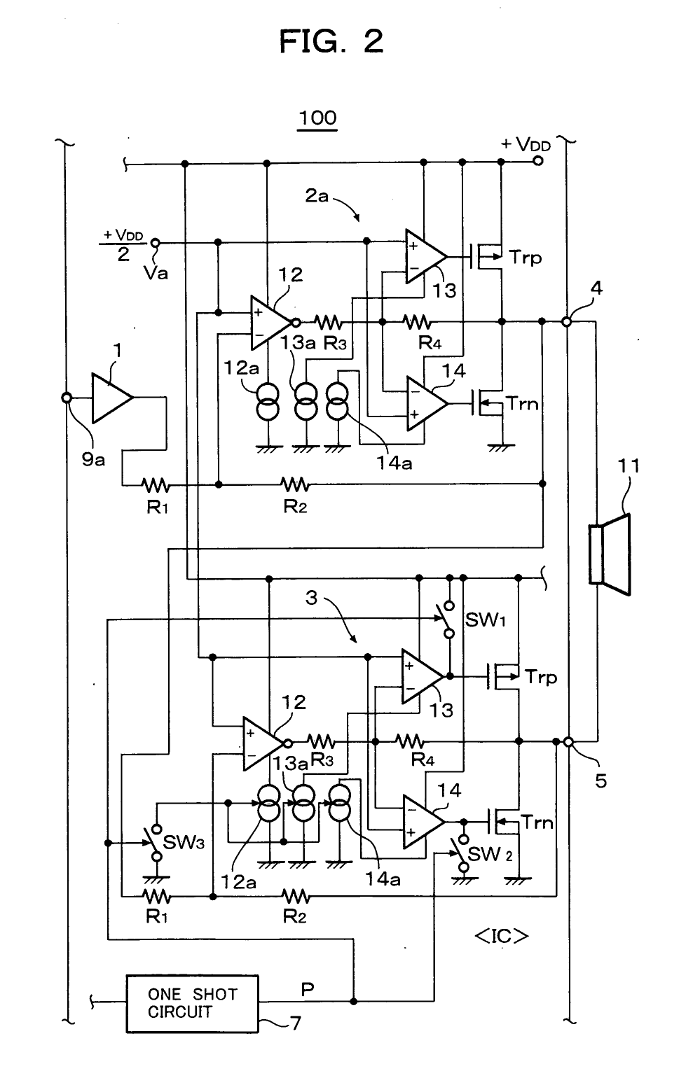

A BTL audio amplifier apparatus 100 formed in an IC as shown in FIG. 2 uses respective push-pull structured transistors TrP, TrN for the output stage amplifier (OP) 3 as the respective switches in place of the provision of the analog switch 6 and these transistors TrP, TrN are turned OFF for a predetermined interval by a pulse P from the one shot circuit 7. Thereby, the output terminal 5 in the BTL audio amplifier apparatus 100 is set at a high impedance to put in a mute state.

Further, an output stage amplifier (OP) 2a in FIG. 2 is different from the output stage amplifier (OP) 2 and is an inverting amplifier like the output stage amplifier (OP) 3. Further, an input of the preamplifier 1 is connected to an input terminal 9a to which an external signal is input.

The circuit structure of the output stage amplifiers (OP) 2a and 3 is fundamentally the same, in that each of the amplifiers is constituted by an input stage differential amplifier 12 and drive stage differential amplifiers 13 and 14.

The drive stage differential amplifier 13 drives the transistor TrP and the drive stage differential amplifier 14 drives the transistor TrN.

Resistors R1 and R2 are respectively a reference resistor and a feed back resistor for determining the amplification rate of the respective output stage amplifiers (OP) 2a and 3. Resistors R3 and R4 are the like resistors and a double feed back circuit is formed by these resistors. Further, the resistance of the resistors R2 and R4 is set at a high resistance value more than a few hundreds k Ω, thereby, when the transistors TrP and TrN are turned OFF, the output terminal 5 is rendered at a high impedance.

A difference between the output stage amplifiers (OP) 2a and 3 is that in the output stage amplifier (OP) 3, a switch circuit SW1 is provided between the gate of the transistor TrP and the power source line +VDD and a switch circuit SW2 is provided between the gate of the transistor TrN and the ground GND. Further, for constant current sources 12a, 13a and 14a which are respectively operation current sources for the input stage differential amplifier 12 and the drive stage differential amplifiers 13 and 14, a switch circuit SW3 is provided for interrupting the current from these current sources.

During a mute interval, in the output stage amplifier (OP) 3, in order to turning OFF the transistors TrP and TrN, the switch circuit SW3 is turned ON and the respective operation currents of the input stage differential amplifier 12 and the drive stage differential amplifiers 13 and 14 for driving the transistors TrP and TrN are turned OFF. At the same time, the switch SW1 is turned ON to turn OFF the transistor TrP by setting the gate of the transistor TrP at the power source voltage. Further, at the same time, the switch circuit SW2 is turned ON to turn OFF the transistor TrN by setting the gate of the transistor TrN at the potential of the ground GND. Thereby, the output terminal 5 is set at a high impedance.

Further, in order to turn OFF the respective operation currents of the input stage differential amplifier 12 and the drive stage differential amplifiers 13 and 14, it is sufficient, for example, if the currents of the current mirror connected constant current source transistors in the constant current source circuits for the respective amplifiers are turned OFF. In such instance, if the drive currents for the constant current circuits are rendered “0”, the currents flowing in the constant current sources 12a, 13a and 14a can be easily cut. Of course, if the switch circuit SW3 are inserted respectively in series with these constant current sources 12a, 13a and 14a and are turned OFF, the currents flowing therein can also be cut.

Further, MOSFET transistors can be used for the switch circuits SW1˜SW3 like the transistors TrP and TrN, still further, these switch circuits can be a switch circuit making use of bipolar transistors.

As has been explained above, in the present embodiment, the muting is effected by turning OFF the respective transistors TrP and TrN in the output stage amplifier (OP) 3. Further, in the present embodiment, since the transistors TrP and TrN are turned OFF via the two stage amplifiers of the input stage differential amplifier 12 and the drive stage differential amplifiers 13 and 14, the delay time from the input to the output of the output stage amplifier (OP) 3 is prolonged correspondingly.

Now, the one shot circuit 7 can be a circuit of mute signal generation circuit which generates three mute signals of a first˜a third signal. Namely, the one shot circuit 7 generates the first mute signal to turn ON the switch SW1 for a predetermined interval (mute interval) corresponding to the muting and to render the transistor TrP to turn OFF for the mute interval. Further, through generation of the second mute signal, the switch circuit SW2 is turned ON for the mute interval and the transistor TrN is turned OFF for the mute interval. Still further, through the generation of the third mute signal, the switch circuit SW3 is turned ON for the mute interval corresponding to the muting and the operation currents flowing the respective constant current sources 12a, 13a and 14a for the respective amplifiers are turned OFF for the mute interval. The muting operation of the above instance can be realized, for example, by another circuit in which the switch circuits SW1˜SW3 are respectively inserted in series with respect to the respective object circuits and are turned OFF for effecting muting.

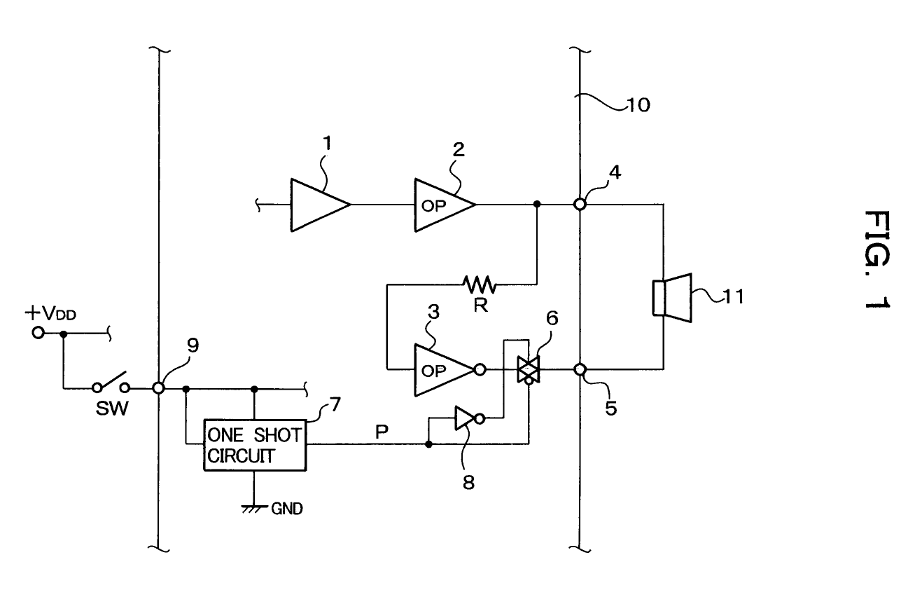

As has been explained hitherto, in the embodiment as shown in FIG. 1, although the analog switch 6 is inserted between the output stage amplifier 3 of an inverting amplification and the output terminal 5, the analog switch 6 can be inserted between the output stage amplifier 2 and the output terminal 4. Further, the switch inserted between these two is not limited to an analog switch.

Further, in the embodiment as shown in FIG. 1, although a non-inverting amplifier is used for the output stage amplifier 2, like the embodiment as shown in FIG. 2, an inverting amplifier can be used for the amplifier. Because regardless to whether the output stage amplifier 2 is an amplifier of an inverting operation or not, if the output stage amplifier 3 is an amplifier of an inverting operation, the output signal of the output stage amplifier 2 and the output stage amplifier 3 show an output relationship of a push operation and a pull operation each other, therefore, a BTL operation can be performed.

Still further, in the embodiments, the switch circuit constituted by the transmission gates of the MOS transistors is exemplified, the transistors in the switch circuit can be, of course, bipolar transistors.

1. A mute circuit in a BTL circuit formed in an IC which drives a speaker by a first output stage amplifier and a second output stage amplifier which generates an inverted output signal with respect to an output signal of the first output stage amplifier, wherein the second output stage amplifier receives the output signal of the first output stage amplifier as an input and generates the inverted output signal, a switch circuit is provided between any one of the outputs of the first and second output stage amplifier and a terminal of the speaker and through a mute signal the switch circuit is turned OFF for a predetermined interval to effect muting.

2. A mute circuit according to claim 1, further comprising a mute signal generation circuit for generating the mute signal, wherein the second output stage amplifier receives the output signal of the first output stage amplifier via a resistor, the switch circuit is an analog switch and the mute signal is a pulse signal having a predetermined width which is generated when a power source is turned ON or OFF.

3. A mute circuit according to claim 2, wherein the mute signal generation circuit is an one shot circuit and the one shot circuit generates the pulse signal having a pulse width of less than a few tens m sec. in response to a turning ON signal of the power source.

4. A mute circuit according to claim 1, wherein each of the first and second output stage amplifier is an operational amplifier of which output stage is constituted by a push-pull structured transistors, the switch circuit is constituted through turning OFF the respective transistors of one of the first output stage amplifier and the second output stage amplifier for a predetermined interval by the mute signal and an output of the one of the first output stage amplifier and the second output stage amplifier is set at a high impedance.

5. A mute circuit according to claim 4, wherein the second output stage amplifier receives the output signal of the first output stage amplifier via a resistor, the switch circuit is an analog switch and the mute signal is a pulse signal having a predetermined width which is generated when a power source is turned ON or OFF.

6. A BTL audio amplifier apparatus formed in an IC which drives a speaker by a first output stage amplifier and a second output stage amplifier which generates an inverted output signal with respect to an output signal of the first output stage amplifier, wherein the second output stage amplifier receives the output signal of the first output stage amplifier as an input and generates the inverted output signal, a first switch circuit is provided between any one of the outputs of the first and second output stage amplifier and a terminal of the speaker and through a mute signal the first switch circuit is turned OFF for a predetermined interval to effect muting.

7. A BTL audio amplifier apparatus according to claim 6, further comprising a mute signal generation circuit for generating the mute signal, wherein the second output stage amplifier receives the output signal of the first output stage amplifier via a resistor, the first switch circuit is an analog switch and the mute signal is a pulse signal having a predetermined width which is generated when a power source is turned ON or OFF.

8. A BTL audio amplifier apparatus according to claim 7, wherein the mute signal generation circuit is an one shot circuit and the one shot circuit generates the pulse signal having a pulse width of less than a few tens m sec. in response to a turning ON signal of the power source.

9. A BTL audio amplifier apparatus according to claim 6, wherein each of the first and second output stage amplifier is an operational amplifier of which output stage is constituted by a push-pull structured transistors, the first switch circuit is constituted through turning OFF the respective transistors of one of the first output stage amplifier and the second output stage amplifier for a predetermined interval by the mute signal and an output of the one of the first output stage amplifier and the second output stage amplifier is set at a high impedance.

10. A BTL audio amplifier apparatus according to claim 9, wherein the second output stage amplifier receives the output signal of the first output stage amplifier via a resistor, the switch circuit is an analog switch and the mute signal is a pulse signal having a predetermined width which is generated when a power source is turned ON or OFF.

11. A BTL audio amplifier apparatus according to claim 10, further comprising a plurality of second switch circuits provided in any one of the first and second output stage amplifier, wherein the respective first and second output stage amplifier are provided with a plurality of drive circuits for driving the respective transistors, and through interrupting operation currents of the plurality of drive circuits upon receiving the mute signal by the plurality of the second switch circuits and through turning OFF the transistors, any one of the outputs of the first and second output stage amplifier is set at a high impedance.

12. A BTL audio amplifier apparatus according to claim 11, wherein the drive circuit is a differential amplifier circuit, the second switch circuits interrupt the operation currents of the plurality of the differential amplifiers in the second output stage amplifier and turns OFF the transistors.
